(19) United States
(12) Patent Application Publication
(10) Pub. No.: US 2022/0108936 A1
(43) Pub. Date: Apr. 7, 2022

(54) SEMICONDUCTOR MODULE

(71) Applicant: Murata Manufacturing Co., Ltd., Kyoto-fu (JP)

(72) Inventors: Shunji YOSHIMI, Nagaokakyo-shi (JP); Yuji TAKEMATSU, Nagaokakyo-shi (JP); Yukiya YAMAGUCHI, Nagaokakyo-shi (JP); Takanori UEJIMA, Nagaokakyo-shi (JP); Satoshi GOTO, Nagaokakyo-shi (JP); Satoshi ARAYASHIKI, Nagaokakyo-shi (JP)

(73) Assignee: Murata Manufacturing Co., Ltd., Kyoto-fu (JP)

(21) Appl. No.: 17/494,611

(22) Filed: Oct. 5, 2021

(30) Foreign Application Priority Data
Oct. 7, 2020 (JP) 2020-169895

(51) Int. Cl. H01L 23/367; H01L 23/66; H01L 23/31

(52) U.S. Cl. CPC H01L 23/3675; H01L 23/66; H01L 23/3107; H01L 2223/6611; H03F 1/302; H01L 2223/6683; H01L 2223/6655; H03F 2200/447; H01L 2223/6616

(57) ABSTRACT

In a semiconductor module, a first conductive portion is raised on a lower surface of a first member to which a second member including a semiconductor element and being smaller than the first member in plan view is joined. A second conductive portion is raised at the second member in the same direction as the first conductive portion. The first and second members are mounted on a module substrate with the interposed first and second conductive portions. A sealing material is disposed on a mounting surface of the module substrate, while covering at least an area of the first member. The sealing material has a top surface facing in the same direction as the top surface of the first member and side surfaces connected to its top surface. A metal film is disposed on the top and side surfaces of the sealing material and side surfaces of the module substrate.

### CROSS-REFERENCE TO RELATED APPLICATION

This application claims benefit of priority to Japanese Patent Application No. 2020-169895 filed Oct. 7, 2020, the entire content of which is incorporated herein by reference.

### BACKGROUND

### Technical Field

The present disclosure relates to a semiconductor module.

### Background Art

Radio-frequency (RF) front-end modules capable of both transmitting and receiving radio-frequency signals are installed in electronic devices for communications such as mobile communications and satellite communications. An RF front-end module includes, for example, a monolithic microwave integrated circuit (MMIC) capable of amplifying radio-frequency signals, a control integrated circuit (IC) for controlling a radio-frequency amplifier circuit, a switch IC, and a duplexer.

U.S. Patent Application Publication No. 2015/0303971 discloses a miniaturized structure formed by stacking a control IC on an MMIC. The module disclosed in U.S. Patent Application Publication No. 2015/0303971 includes the MMIC mounted on a module substrate and the control IC stacked on the MMIC. Electrodes of the MMIC, electrodes of the control IC, and electrodes on the module substrate are electrically coupled to each other by wire bonding.

### SUMMARY

In a radio-frequency amplifier circuit, for example, a heterojunction bipolar transistor (HBT) is utilized. While an HBT operates, the HBT generates heat because collector dissipation occurs. A temperature rise of the HBT caused by heat generation in turn increases collector current. When conditions for this positive feedback are satisfied, thermal runaway occurs in the HBT. To avoid thermal runaway in the HBT, an upper limit of output power of the HBT is set.

To implement radio-frequency amplifier circuits with high power output, it is desirable to improve the characteristic of heat released from a semiconductor element constituting an MMIC, such as an HBT. It is difficult to satisfy recent demand for radio-frequency amplifier circuits with high power output by using the module structure disclosed in U.S. Patent Application Publication No. 2015/0303971. Accordingly, the present disclosure provides a semiconductor module that can improve the characteristic of heat released from a semiconductor element.

An aspect of the present disclosure provides a semiconductor module including a first member, a first conductive raised portion, a second member, a second conductive raised portion, a module substrate, a sealing material, and a metal film. The first member has a lower surface and a top surface facing away from each other. The first conductive raised portion is disposed on the lower surface of the first member. The second member is joined to the lower surface of the first member. The second member is smaller than the first member in plan view. The second member includes a semiconductor element inside. The second conductive raised portion is disposed at the second member. The second conductive raised portion is raised in a direction identical to a direction in which the first conductive raised portion is raised. The first member and the second member are mounted on the module substrate with the first conductive raised portion interposed between the module substrate and the first member and with the second conductive raised portion interposed between the module substrate and the second member. The sealing material is disposed on a surface of the module substrate. The first member and the second member are mounted on the surface of the module substrate. The sealing material covers at least an area of a surface of the first member. The sealing material has a top surface facing in a direction identical to a direction in which the top surface of the first member faces and also has side surfaces connected to the top surface of the sealing material. The metal film is disposed on the top surface of the sealing material, the side surfaces of the sealing material, and side surfaces of the module substrate.

Two heat transfer paths are formed. Heat generated at the semiconductor element included in the second member is transferred along one of the heat transfer paths through the second conductive raised portion to the module substrate; and the heat is transferred along the other of the heat transfer paths through the first member and the sealing material to the metal film. The heat transferred to the metal film diffuses over almost the entire part of the metal film covering the top and side surfaces of the sealing material, and the heat is consequently released from almost the entire part of the metal film. As a result, the characteristic of releasing heat from the semiconductor element included in the second member 40 can be improved.

Other features, elements, characteristics and advantages of the present disclosure will become more apparent from the following detailed description of preferred embodiments of the present disclosure with reference to the attached drawings.

### BRIEF DESCRIPTION OF THE DRAWINGS

FIG. 1 illustrates an arrangement of components of a semiconductor module according to a first embodiment when the semiconductor module is viewed in plan view;

FIG. 2A is a sectional view taken along a dot-dash line 2A-2A in FIG. 1;

FIG. 2B is an enlarged sectional view of a part including a semiconductor device;

FIG. 3 is an enlarged sectional view of one semiconductor element included in a second member;

FIG. 4 is a sectional view of the semiconductor device installed in the semiconductor module according to the first embodiment;

FIG. 5 is a block diagram illustrating a circuit configuration of the semiconductor module according to the first embodiment;

FIGS. 6A to 6F provide schematic sectional views of the semiconductor device during a manufacturing process;

FIGS. 7A and 7B provide schematic sectional views of the semiconductor device during a manufacturing process;

FIG. 7C provides a schematic sectional view of the finished semiconductor device;

FIG. 8 is a sectional view in the state in which the semiconductor module according to the first embodiment is mounted on a motherboard;

FIG. 9 is a sectional view in the state in which a semiconductor module according to a second embodiment is mounted on a motherboard;

FIG. 10A illustrates an arrangement of components of a semiconductor module according to a third embodiment when the semiconductor module is viewed in plan view;

FIG. 10B is a sectional view taken along a dot-dash line 10B-10B in FIG. 10A;

FIG. 11 is a sectional view in the state in which a semiconductor module according to a fourth embodiment is mounted on a motherboard; and

FIG. 12 is a sectional view of a semiconductor device including a semiconductor module according to a fifth embodiment.

### DETAILED DESCRIPTION

### First Embodiment

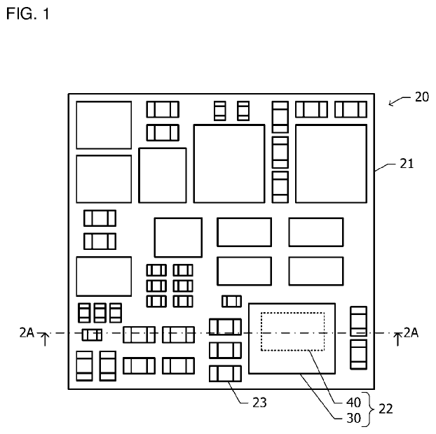

A semiconductor module according to a first embodiment will be described with reference to FIGS. 1 to 8.

FIG. 1 illustrates an arrangement of components of a semiconductor module 20 according to the first embodiment when the semiconductor module 20 is viewed in plan view. A semiconductor device 22 and other surface mount devices 23 are mounted on a module substrate 21. The surface mount devices 23 include, for example, passive components such as an inductor, a capacitor, a resistance element, and a filter and active components such as a switch integrated circuit (IC) and a low-noise amplifier. The semiconductor device 22 includes a first member 30 and a second member 40 joined to a lower surface (surface facing the module substrate 21) of the first member 30. When viewed in plan view, the second member 40 is smaller than the first member 30, and the second member 40 is surrounded by the first member 30. For example, the first member 30 is made from an elemental semiconductor, and the second member 40 is made from a compound semiconductor.

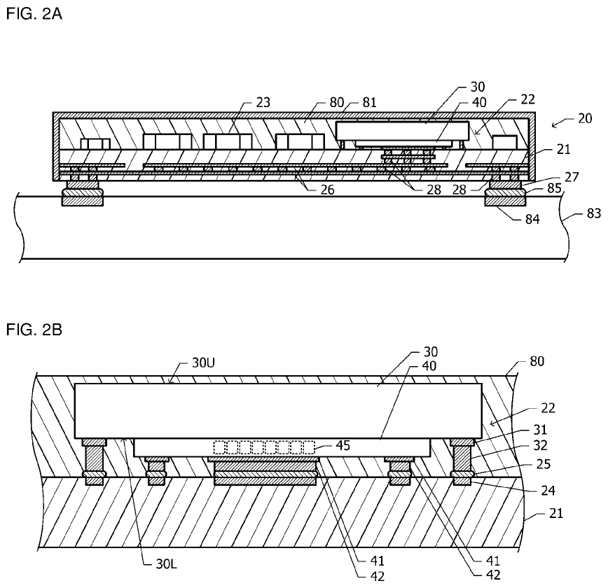

FIG. 2A is a sectional view taken along a dot-dash line 2A-2A in FIG. 1. FIG. 2B is an enlarged sectional view of a part including the semiconductor device 22. In FIG. 2A, a semiconductor chip according to the first embodiment is mounted on a motherboard.

Firstly, a structure of the semiconductor device 22 will be described with reference to FIG. 2B. The semiconductor device 22 includes the plate-like first member 30 and the film-like second member 40 joined to the first member 30. Of two surfaces of the first member 30 perpendicular to the thickness direction, the surface facing the module substrate 21 is referred to as a lower surface 30L, and the surface opposite to the lower surface is referred to as a top surface 30U. The second member 40 is joined to the lower surface 30L of the first member 30. The second member 40 is thermally coupled to the first member 30. The second member 40 includes a plurality of semiconductor elements 45. The plurality of semiconductor elements 45 are each a compound semiconductor element such as a heterojunction bipolar transistor (HBT).

A plurality of pads 31 are disposed at an area of the lower surface 30L of the first member 30 not overlapping the second member 40. A first conductive raised portion 32 is disposed on each of the plurality of pads 31 (on a surface toward the same direction as the lower surface 30L). A plurality of pads 41 are disposed on a surface of the second member 40 facing the module substrate 21 (on a surface toward the same direction as the lower surface 30L of the first member 30). A second conductive raised portion 42 is disposed on each of the plurality of pads 41. The first conductive raised portion 32 disposed at the first member 30 and the second conductive raised portion 42 disposed at the second member 40 are raised from the first member 30 or the second member 40 in the same direction. At least one of the second conductive raised portions 42 is disposed under the plurality of semiconductor elements 45 in plan view.

A plurality of lands 24 are disposed on an upper surface of the module substrate 21. The first conductive raised portions 32 provided at the first member 30 and the second conductive raised portion 42 provided at the second member 40 are individually joined to the lands 24 at the module substrate 21 by solder joints 25. As described above, the semiconductor device 22 including the first member 30 and the second member 40 is mounted on the module substrate 21 by flip chip bonding.

As illustrated in FIG. 2A, the other surface mount devices 23 are mounted on the module substrate 21 in addition to the semiconductor device 22. At least one layer of ground plane 26 is provided as an inner layer of the module substrate 21. Of the second conductive raised portions 42 (FIG. 2B) at the second member 40, one second conductive raised portion 42 disposed under the semiconductor elements 45 in plan view is electrically and thermally coupled to the ground plane 26 (FIG. 2A) via the solder joint 25 (FIG. 2B), the land 24 (FIG. 2B), and a via hole 28 (FIG. 2A) in the module substrate 21.

A plurality of connection terminals 27 are disposed on a lower surface (surface opposite to the surface with the semiconductor device 22) of the module substrate 21. At least one of the connection terminals 27 is coupled to the ground plane 26 via the via hole 28.

The upper surface of the module substrate 21, and the semiconductor device 22 and the surface mount devices 23 mounted on the module substrate 21 are covered with a sealing material 80. Of surfaces of the sealing material 80, a surface toward the same direction as the top surface of the first member 30 is referred to as a top surface, and surfaces extending from edges of the top surface to the module substrate 21 are referred to as side surfaces. The side surfaces of the sealing material 80 are smoothly connected to side surfaces of the module substrate 21.

The top surface and side surfaces of the sealing material 80 and the side surfaces of the module substrate 21 are covered by a metal film 81. The metal film 81 can be formed from, for example, Cu or Al by employing a technique such as sputtering. The metal film 81 is connected to the ground plane 26 at the side surfaces of the module substrate 21. The metal film 81 functions as a shield film for electromagnetically shielding an electronic circuit constituted by the semiconductor device 22 and the surface mount devices 23 mounted on the module substrate 21 from the outside.

A plurality of lands 84 are disposed on an upper surface of a motherboard 83. The plurality of connection terminals 27 at the module substrate 21 are individually connected to the lands 84 at the motherboard 83 by using solder joints 85, so that the semiconductor module 20 is mounted on the motherboard 83.

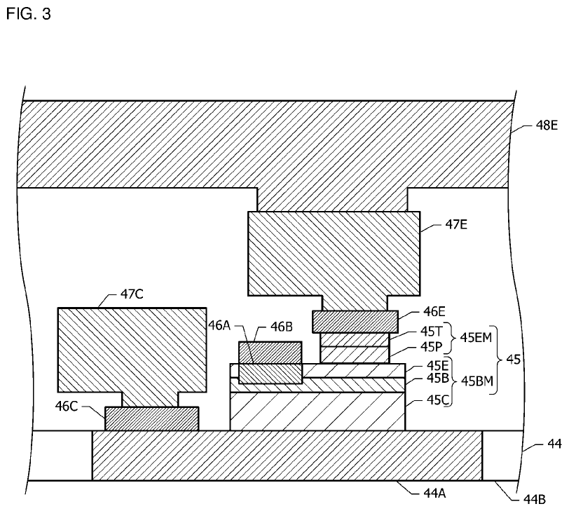

FIG. 3 is an enlarged sectional view of one of the semiconductor elements 45 included in the second member 40 (FIG. 2B). The second member 40 includes a semiconductor thin film 44, the semiconductor elements 45, and various electrodes and wires. The semiconductor thin film 44 is joined to the first member 30 (FIG. 2B). The sectional view illustrated in FIG. 3 is upside down with respect to the sectional views illustrated in FIGS. 2A and 2B. In the description of FIG. 3, the side corresponding to the lower side in FIGS. 2A and 2B is referred to as the upper side.

The semiconductor thin film 44 is formed from a compound semiconductor such as GaAs. The semiconductor thin film 44 is divided into a conductive N-type subcollector layer 44A and a non-conductive element isolation area 44B. The semiconductor element 45 is formed on the subcollector layer 44A.

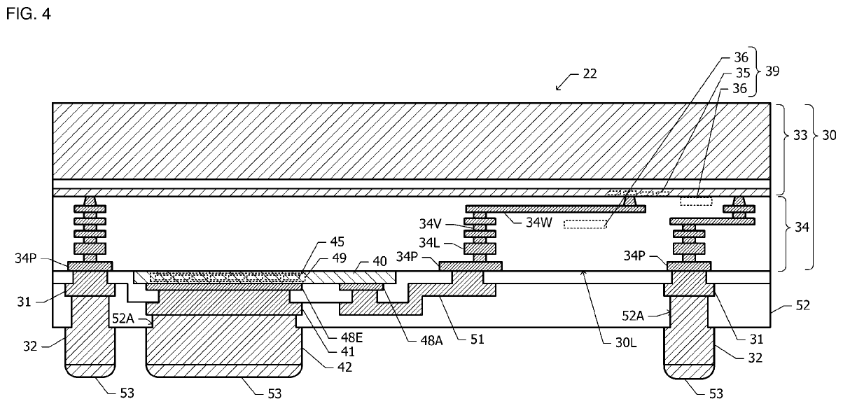

The semiconductor element 45 includes a base mesa 45BM formed on the subcollector layer 44A and an emitter mesa 45EM formed at an area of an upper surface of the base mesa 45BM. The base mesa 45BM includes a collector layer 45C, a base layer 45B, and an emitter layer 45E, which are stacked on the subcollector layer 44A in order. In other words, from the side close to the first member 30 (FIG. 4), the collector layer 45C, the base layer 45B, and the emitter layer 45E are stacked in the order presented. The emitter mesa 45EM includes a cap layer 45P and a contact layer 45T disposed on the cap layer 45P.

For example, the collector layer 45C is made from N-type GaAs, the base layer 45B is made from P-type GaAs, and the emitter layer 45E is made from N-type InGaP; the cap layer 45P is made from N-type GaAs, and the contact layer 45T is made from N-type InGaAs. The semiconductor element 45 constituted by the base mesa 45BM and the emitter mesa 45EM is an HBT. While the semiconductor element 45 operates, heat is generated mainly at the collector layer 45C located under the emitter mesa 45EM.

A collector electrode 46C is disposed on an area of the subcollector layer 44A without the base mesa 45BM. A first-layer collector wire 47C is disposed on the collector electrode 46C. FIG. 3 does not illustrate the specific structure of interlayer insulating films between wiring layers. The collector wire 47C is electrically coupled to the collector layer 45C via the collector electrode 46C and the subcollector layer 44A.

A base electrode 46B is disposed on an area of the emitter layer 45E without the emitter mesa 45EM. The base electrode 46B is electrically coupled to the base layer 45B via an alloyed area 46A extending through the emitter layer 45E in the thickness direction to the base layer 45B.

An emitter electrode 46E is disposed on the emitter mesa 45EM. The emitter electrode 46E is electrically coupled to the emitter layer 45E via the contact layer 45T and the cap layer 45P. The emitter layer 45E located under the emitter mesa 45EM practically functions as an emitter area.

A first-layer emitter wire 47E is disposed on the emitter electrode 46E. A second-layer emitter wire 48E is disposed on the emitter wire 47E. The second-layer emitter wire 48E is electrically coupled to the emitter electrode 46E via the first-layer emitter wire 47E. At least one of the pads 41 (FIG. 2B) is disposed on the second-layer emitter wire 48E. This pad 41 is electrically coupled to the emitter layer 45E of the semiconductor element 45.

FIG. 4 is a sectional view of the semiconductor device 22 installed in the semiconductor module 20 according to the first embodiment (FIG. 2A). Firstly, a structure of the first member 30 will be described.

The first member 30 includes a substrate 33 and a multilayer wiring structure 34 disposed on the substrate 33. For example, a silicon-on-insulator (SOI) substrate may be used as the substrate 33. For example, a general silicon substrate may be used as the substrate 33. The multilayer wiring structure 34 is disposed on the lower surface 30L side with respect to the substrate 33. Elements including a plurality of silicon-based semiconductor elements 35 are formed at a surface layer portion of the substrate 33. The plurality of semiconductor elements 35 form, for example, a complementary metal-oxide semiconductor (CMOS) circuit.

The multilayer wiring structure 34 includes a plurality of wires 34W, a plurality of inner-layer lands 34L, a plurality of via holes 34V for connecting layers, and a plurality of pads 34P disposed on the lower-surface side of the multilayer wiring structure 34. FIG. 4 does not illustrate the structure of interlayer insulating films in the multilayer wiring structure 34. A plurality of passive elements 36 are disposed on the downward surface of the substrate 33 or at an inner layer of the multilayer wiring structure 34. The semiconductor elements 35, the passive elements 36, and elements in the multilayer wiring structure 34 such as the wires 34W, the via holes 34V, and the inner-layer lands 34L together form a first electronic circuit 39. This means that the first member 30 includes the first electronic circuit 39. The plurality of pads 34P are coupled to the first electronic circuit 39.

The second member 40 is joined to an area of the lower surface 30L of the first member 30. Elements including the plurality of semiconductor elements 45 included in the second member 40 form a second electronic circuit 49. This means that the second member 40 includes the second electronic circuit 49. The second member 40 includes the emitter wire 48E (FIG. 3) and a pad 48A, which are disposed on a downward surface of the second member 40.

A redistribution layer is disposed on the first member 30 and the second member 40 (under the first member 30 and the second member 40 in FIG. 4) with an interlayer insulating film interposed therebetween. The structure of the interlayer insulating film between the redistribution layer and the first member 30 and the second member 40 is not described here. The redistribution layer includes the plurality of pads 31, the pads 41, and an inter-member connection wire 51, which are formed by metal patterns. The inter-member connection wire 51 connects the first electronic circuit 39 included in the first member 30 and the second electronic circuit 49 included in the second member 40.

A protection film 52 covers the plurality of pads 31, the pads 41, and the inter-member connection wire 51 included in the redistribution layer. A plurality of openings 52A are provided at the protection film 52. The plurality of pads 31 and the pads 41 include the plurality of openings 52A in plan view. The second conductive raised portion 42 is disposed on each of the plurality of pads 41. The first conductive raised portion 32 is disposed on each of the plurality of pads 31. The first conductive raised portions 32 and the second conductive raised portions 42 are raised downwards from a lower surface of the protection film 52. A solder joint 53 is laid on a downward surface of each of the first conductive raised portions 32 and the second conductive raised portions 42. The first conductive raised portions 32 and the second conductive raised portions 42 are made by using, for example, Cu. In this case, the first conductive raised portion 32 and the solder joint 53 thereon and the second conductive raised portion 42 and the solder joint 53 thereon are each referred to as a Cu pillar bump.

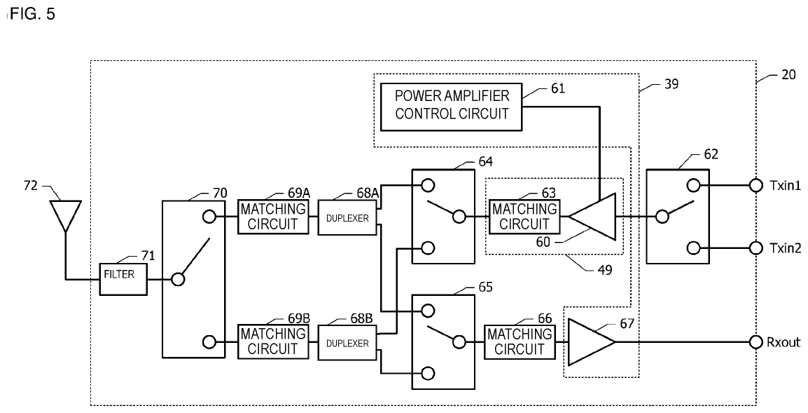

FIG. 5 is a block diagram illustrating a circuit configuration of the semiconductor module 20 according to the first embodiment. The semiconductor module 20 according to the first embodiment has a function of a front-end module for transmitting and receiving radio-frequency signals.

Radio-frequency signals are inputted to two input terminals Txin1 and Txin2. A radio-frequency signal inputted to one of the input terminals Txin1 and Txin2 selected by an input switch 62 is inputted to a power amplifier 60. A power amplifier control circuit 61 controls the operation of the power amplifier 60. The radio-frequency signal is amplified by the power amplifier 60, transferred through a matching circuit 63 and a band selection switch 64, and inputted to either selected duplexer 68A or 68B. This means that the band selection switch 64 has a function of selecting one duplexer for inputting a radio-frequency signal from the two duplexers 68A and 68B.

The two duplexers 68A and 68B are respectively coupled to two contacts of an antenna switch 70 via matching circuits 69A and 69B. One pole of the antenna switch 70 is coupled to an antenna 72 via a filter 71. The radio-frequency signal passed through either the duplexer 68A or 68B is transferred through either the matching circuit 69A or 69B, the antenna switch 70, and the filter 71 to the antenna 72.

By contrast, a radio-frequency signal received by the antenna 72 is passed through the filter 71 and the antenna switch 70, transferred through either the matching circuit 69A or 69B, and inputted to either the duplexer 68A or 68B. The antenna switch 70 has a function of selecting one duplexer for inputting a received radio-frequency signal from the two duplexers 68A and 68B.

The receive signal passed through either the duplexer 68A or 68B is transferred through a band selection switch 65 and a matching circuit 66 and inputted to a low-noise amplifier 67. The band selection switch 65 has a function of selecting one duplexer for passing a receive signal from the two duplexers 68A and 68B. The receive signal is amplified by the low-noise amplifier 67 and outputted from a receive-signal output terminal Rxout.

The second electronic circuit 49 of the second member 40 (FIG. 4) includes the power amplifier 60 and the matching circuit 63. The first electronic circuit 39 of the first member 30 (FIG. 4) includes the power amplifier control circuit 61 and the low-noise amplifier 67. The surface mount devices 23 (FIGS. 1 and 2A) mounted on the module substrate 21 implement the input switch 62, the band selection switch 64, 65, the duplexers 68A and 68B, the matching circuits 66, 69A, and 69B, the antenna switch 70, and the filter 71.

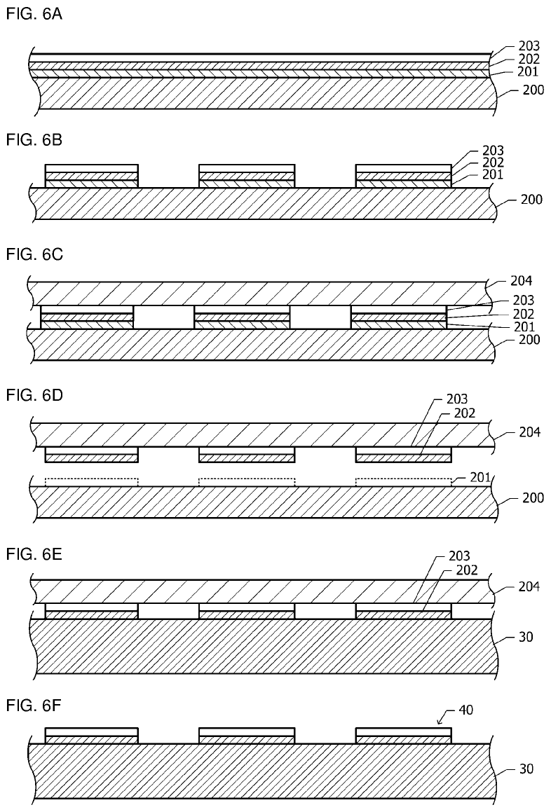

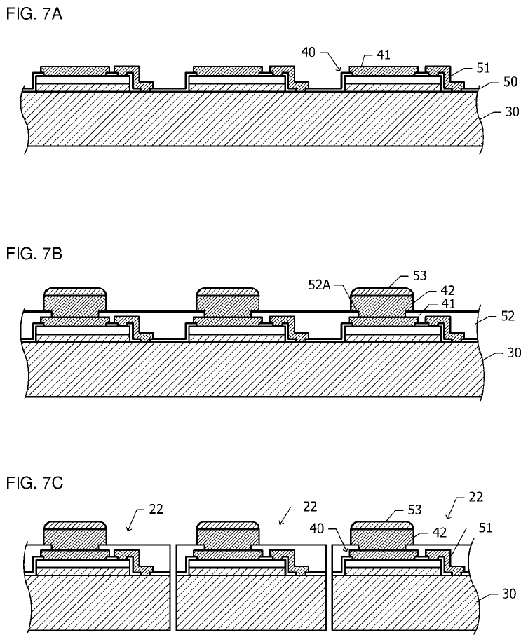

Next, a method of manufacturing the semiconductor device 22 (FIG. 4) will be described with reference to drawings in FIGS. 6A to 7C. The drawings in FIGS. 6A to 7B provide schematic sectional views of the semiconductor device 22 during a manufacturing process. FIG. 7C provides a schematic sectional view of the finished semiconductor device 22.

As illustrated in FIG. 6A, a release layer 201 is epitaxially grown on a single-crystal base substrate 200 made from a compound semiconductor such as GaAs, and an element formation layer 202 is formed on the release layer 201. Element structures including the semiconductor element 45, the emitter electrode 46E, the collector electrode 46C, the base electrode 46B, the emitter wire 47E, the collector wire 47C, and the second-layer emitter wire 48E, which are illustrated in FIG. 3, are formed at the element formation layer 202. These element structures are formed in accordance with a general semiconductor manufacturing process. FIG. 6A does not illustrate the element structures formed at the element formation layer 202. In this stage, an element structure corresponding to a plurality of second members 40 (FIG. 2A) is formed at the element formation layer 202, so that the individual second members 40 are not yet separated from each other. An insulating protection film 203 is formed on the element formation layer 202.

Next, as illustrated in FIG. 6B, the protection film 203, the element formation layer 202, and the release layer 201 are subjected to patterning by using a resist pattern (not illustrated in the drawing) as an etch mask. In this stage, the element formation layer 202 is divided into the individual second members 40 (FIG. 2A).

Next, as illustrated in FIG. 6C, a connecting support 204 is bonded on the divided protection films 203. As a result, the plurality of protection films 203 are connected to each other by the connecting support 204. The resist pattern used as an etch mask in the patterning step of FIG. 6B may be left so that the resist pattern exists between the protection film 203 and the connecting support 204.

Next, as illustrated in FIG. 6D, the release layer 201 corresponding to the base substrate 200 and the element formation layer 202 is selectively etched. As a result, the element formation layer 202, the protection film 203, and the connecting support 204 are released from the base substrate 200. To selectively etch the release layer 201, the release layer 201 is formed from a compound semiconductor having an etch resistance different from both the etch resistance of the base substrate 200 and the etch resistance of the element formation layer 202.

Next, as illustrated in FIG. 6E, the element formation layer 202 is joined to the first member 30. In this stage, the first member 30 is not divided into individual pieces illustrated in FIGS. 2A and 2B, and one wafer includes a plurality of first members 30. FIG. 6E does not illustrate the structure of the first electronic circuit 39 and the multilayer wiring structure 34 formed at the first member 30, which are illustrated in FIG. 4.

The element formation layer 202 and the first member 30 are joined to each other by the Van der Waals force or hydrogen bonding. The element formation layer 202 may be joined to the first member 30 by, for example, static electricity, covalent bonding, or eutectic alloy bonding. For example, the element formation layer 202 and the first member 30 may be joined to each other by forming an Au film at an area of a surface of the first member 30 and apply pressure in the state in which the element formation layer 202 is in close contact with the Au film.

Next, as illustrated in FIG. 6F, the connecting support 204 is released from the protection film 203. After these steps, a structure is obtained in which the individual second members 40 are joined on the wafer including a plurality of first members 30.

After releasing the connecting support 204, as illustrated in FIG. 7A, an interlayer insulating film 50 and the redistribution layer are formed over the first member 30 and the second member 40. The redistribution layer includes, for example, the pads 41 disposed on the second member 40 and the inter-member connection wire 51 (FIG. 4) extending from the top of the second member 40 across the edges of the second member 40 to the top of the first member 30. The redistribution layer includes the pads 31 (FIG. 4) disposed on the first member 30, but the pads 31 are not illustrated in FIG. 7A.

Next, as illustrated in FIG. 7B, the protection film 52 is formed on redistribution layer, and the plurality of openings 52A are formed at the protection film 52. The pads 41 and 31 (FIG. 4) include the plurality of openings 52A in plan view. The second conductive raised portions 42 and the first conductive raised portions 32 (FIG. 4) are formed in the openings 52A and on the protection film 52. The reflow process is performed in the state in which the solder joints 53 are laid on top surfaces of the first conductive raised portion 32 and top surfaces of the second conductive raised portions 42.

Finally, as illustrated in FIG. 7C, the wafer including the plurality of first members 30 are cut with a dicing machine. This yields the semiconductor device 22 as an individual piece including, for example, the first member 30, the second member 40, the redistribution layer thereon, and the second conductive raised portions 42 and the first conductive raised portions 32 (FIG. 4).

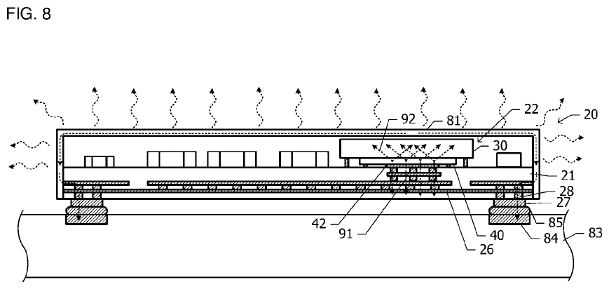

Next, advantageous effects of the first embodiment will be described with reference to FIG. 8. FIG. 8 is a sectional view in the state in which the semiconductor module 20 according to the first embodiment is mounted on the motherboard 83. A first heat transfer path 91 and a second heat transfer path 92 are formed. The first heat transfer path 91 starts from the semiconductor elements 45 (FIG. 2B) of the second member 40, passes through the second conductive raised portion 42 (FIG. 2B) provided at the second member 40, and reaches the module substrate 21. The second heat transfer path 92 starts from the semiconductor elements 45 (FIG. 2B) of the second member 40, passes through the first member 30 and the sealing material 80, and reaches the metal film 81.

The heat transferred to the first member 30 diffuses in the first member 30. Usually, the thermal conductivity of a main material of the substrate 33 at which the silicon-based semiconductor element 35 (FIG. 4) is formed is higher than the thermal conductivity of a main material of the second member 40 at which the compound semiconductor element 45 is formed. Hence, heat transferred to the first member 30 is easy to diffuse in the first member 30. The heat diffusing in the first member 30 is transferred through the sealing material 80 to the metal film 81. The heat diffusing in the first member 30 is transferred mainly from the top surface of the first member 30 to the metal film 81 over the first member 30.

The thermal conductivity of the metal film 81 is higher than the thermal conductivity of the sealing material 80 usually made from, for example, a resin. Hence, the heat transferred to the metal film 81 along the second heat transfer path 92 is subsequently transferred through the metal film 81 covering the top surface of the sealing material 80 to the metal film 81 covering the sealing material 80 and the side surfaces of the module substrate 21. Because heat is released from almost the entire part of the metal film 81, this structure can improve the characteristic of releasing heat transferred to the metal film 81 along the second heat transfer path 92.

The heat transferred to side surfaces of the metal film 81 is further transferred to the motherboard 83 through the ground plane 26 in the module substrate 21, the via hole 28, the connection terminal 27 in the module substrate 21, the solder joint 85, and the land 84 of the motherboard 83. As such, heat generated at the second member 40 is transferred to the motherboard 83 along both the first heat transfer path 91 and the second heat transfer path 92. Thus, the characteristic of releasing heat from the second member 40 can be improved.

The electron mobility in compound semiconductors such as GaAs is greater the electron mobility in silicon. Because the power amplifier 60 (FIG. 5) is constituted by the semiconductor elements 45 formed by a compound semiconductor layer epitaxially grown on the semiconductor thin film 44 (FIG. 3) formed from a compound semiconductor, it is possible to increase the operating frequency of the power amplifier 60.

Because the characteristic of releasing heat from the second member 40 can be improved as described above, it is possible to suppress rises in temperature of the semiconductor elements 45 included in the second member 40.

Next, modifications to the first embodiment will be described. Although in the first embodiment the first member 30 includes the first electronic circuit 39 (FIG. 4), the first member 30 does not necessarily include any electronic circuit, and a member especially for a heat spreader may be used as the first member 30 to achieve heat diffusion. In this case, the first conductive raised portion 32 (FIG. 4) provided at the first member 30 functions as a heat transfer path for transferring heat from the first member 30 to the module substrate 21.

Although in the first embodiment a silicon semiconductor element is used as the semiconductor element 35 (FIG. 4) formed at the first member 30, other elemental semiconductor elements such as a germanium semiconductor element may be used.

In the first embodiment, for example, the first conductive raised portion 32 and the solder joint 53 thereon and the second conductive raised portion 42 and the solder joint 53 thereon are used as electrodes for mounting the semiconductor device 22 on the module substrate 21, but other various conductive raised portions may be used. For example, pillars, posts, or ball bumps made from a conductor may be used as conductive raised portions for external connection.

### Second Embodiment

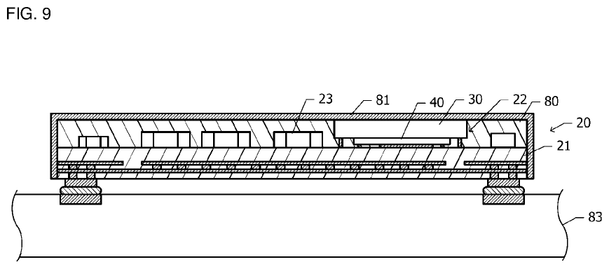

Next, a semiconductor module according to a second embodiment will be described with reference to FIG. 9. The following description does not repeat configurations common to the semiconductor module according to the first embodiment described with reference to FIGS. 1 to 8.

FIG. 9 is a sectional view in the state in which the semiconductor module 20 according to the second embodiment is mounted on the motherboard 83. In the first embodiment (FIG. 2A), the sealing material 80 is interposed between the top surface of the first member 30 and the metal film 81. By contrast, in the second embodiment, the top surface of the first member 30 is exposed from the sealing material 80 to contact the metal film 81.

Next, a method of manufacturing the semiconductor module according to the second embodiment will be described. A plurality of the semiconductor devices 22 (FIG. 2A) and the surface mount devices 23 (FIG. 2A) are mounted on a printed circuit board before division at which a plurality of the module substrates 21 (FIG. 2A) are formed. Subsequently, the sealing material 80 is formed on the printed circuit board by injection molding. After the sealing material 80 is formed, the top surface of the sealing material 80 is polished or ground to expose the top surface of the first member 30. Subsequently, the printed circuit board and the sealing material 80 are cut with a dicing machine to be divided into individual pieces. After the individual pieces are made, the metal film 81 is deposited by, for example, sputtering over the top and side surfaces of the sealing material 80 and the side surfaces of the module substrate 21.

Next, advantageous effects of the second embodiment will be described. In the second embodiment, the top surface of the first member 30 and the metal film 81 are in contact with each other without the sealing material 80 interposed therebetween, and as a result, it is possible to reduce the thermal resistance in the heat transfer path from the first member 30 to the metal film 81. This can further improve the characteristic of releasing heat from the second member 40.

Next, a modification to the method of manufacturing the semiconductor module according to the second embodiment will be described. In this modification, injection molding is carried out while the top surface of the first member 30 is in close contact with a mold for injection molding. This can expose the top surface of the first member 30 from the sealing material 80 without polishing or grinding the top surface of the sealing material 80.

### Third Embodiment

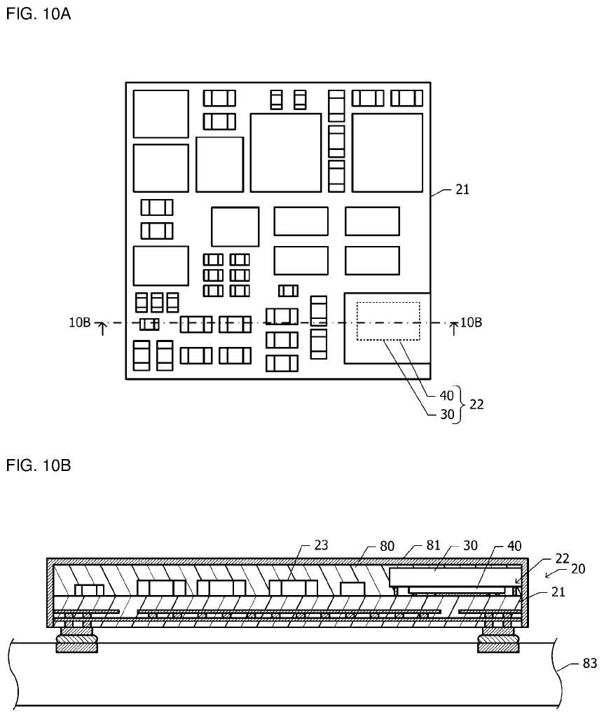

Next, a semiconductor module according to a third embodiment will be described with reference to FIGS. 10A and 10B. The following description does not repeat configurations common to the semiconductor module according to the first embodiment described with reference to FIGS. 1 to 8.

FIG. 10A illustrates an arrangement of components of the semiconductor module 20 according to the third embodiment when the semiconductor module 20 is viewed in plan view. FIG. 10B is a sectional view taken along a dot-dash line 10B-10B in FIG. 10A. In the first embodiment (FIG. 1), when the semiconductor module 20 is viewed in plan view, the semiconductor device 22 is spaced apart from edges of the module substrate 21 and positioned in an inner area the module substrate 21. By contrast, in the third embodiment, an edge of the first member 30 of the semiconductor device 22, which is substantially rectangular in plan view, coincides with an edge of the module substrate 21 as illustrated in FIG. 10A.

As illustrated in FIG. 10B, one side surface of the first member 30 is level with one side surface of the sealing material 80 so that the first member 30 is exposed from the sealing material 80. Thus, the metal film 81 covering the side surfaces of the sealing material 80 is in contact with the first member 30 without the sealing material 80 interposed therebetween.

Next, a method of manufacturing the semiconductor module according to the third embodiment will be described. A plurality of the semiconductor devices 22 (FIG. 2A) and the surface mount devices 23 (FIG. 2A) are mounted on a printed circuit board before division at which a plurality of the module substrates 21 (FIG. 2A) are formed. At this time, the semiconductor device 22 is positioned at a location that enables one edge of the first member 30 to contact or slightly overlap the dicing cut line.

Subsequently, the sealing material 80 is formed on the printed circuit board by injection molding. After the sealing material 80 is formed, the printed circuit board and the sealing material 80 are cut with a dicing machine to be divided into individual pieces. At this time, one side surface of the sealing material 80 is level with one side surface of the first member 30. After the individual pieces are made, the metal film 81 is deposited by, for example, sputtering over the top and side surfaces of the sealing material 80 and the side surfaces of the module substrate 21.

Next, advantageous effects of the third embodiment will be described. In the third embodiment, one side surface of the first member 30 and the metal film 81 are in contact with each other without the sealing material 80 interposed therebetween, and as a result, it is possible to reduce the thermal resistance in the heat transfer path from the first member 30 to the metal film 81. This can further improve the characteristic of releasing heat from the second member 40.

Next, modifications to the third embodiment will be described. In the third embodiment, an edge of the first member 30 of the semiconductor device 22, which is substantially rectangular in plan view, coincides with an edge of the module substrate 21. However, two adjacent edges of the first member 30 may coincide with two adjacent edges of the module substrate 21. In this case, two adjacent side surfaces of the first member 30 contact the metal film 81, and as a result, it is possible to further reduce the thermal resistance from the first member 30 to the metal film 81. This can further improve the characteristic of releasing heat from the second member 40.

Furthermore, although in the third embodiment one side surface of the first member 30 is level with one side surface of the sealing material 80, both one side surface of the first member 30 and one side surface of the second member 40 may be level with one side surface of the sealing material 80. This can further improve the characteristic of releasing heat from the second member 40.

### Fourth Embodiment

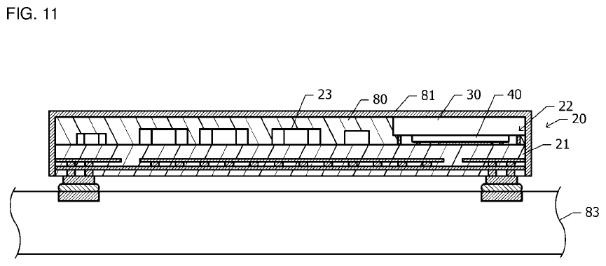

Next, a semiconductor module according to a fourth embodiment will be described with reference to FIG. 11. The following description does not repeat configurations common to the semiconductor module 20 according to the second embodiment (FIG. 9) and the third embodiment (FIGS. 10A and 10B).

FIG. 11 is a sectional view in the state in which the semiconductor module 20 according to the fourth embodiment is mounted on the motherboard 83. In the second embodiment (FIG. 9), the top surface of the first member 30 is in contact with the metal film 81, whereas in the third embodiment (FIGS. 10A and 10B) one side surface of the first member 30 is in contact with the metal film 81. By contrast, in the fourth embodiment, both the top surface and one side surface of the first member 30 are in contact with the metal film 81. Such a structure is formed by polishing or grinding the top surface of the sealing material 80 similarly to the second embodiment before the dicing process in the third embodiment.

Next, advantageous effects of the fourth embodiment will be described. The interface at which the first member 30 contacts the metal film 81 in the fourth embodiment is larger than the interface in the second embodiment and the interface in the third embodiment. Thus, it is possible to further reduce the thermal resistance in the heat transfer path from the first member 30 to the metal film 81. This can further improve the characteristic of releasing heat from the second member 40.

### Fifth Embodiment

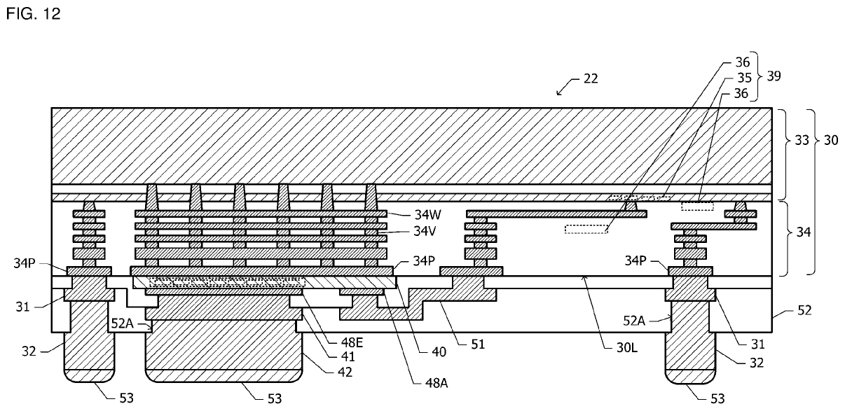

Next, a semiconductor module according to a fifth embodiment will be described with reference to FIG. 12. The following description does not repeat configurations common to the semiconductor module according to the first embodiment described with reference to FIGS. 1 to 8.

FIG. 12 is a sectional view of the semiconductor device 22 including the semiconductor module 20 according to the fifth embodiment. In the first embodiment (FIG. 4), no wire and via hole are disposed in an area of the multilayer wiring structure 34 coinciding with the second member 40 in plan view. By contrast, in the fifth embodiment, the pad 34P, a plurality of wires 34W stacked in the thickness direction, and a plurality of via holes 34V are disposed in the area coinciding with the second member 40 in plan view. The plurality of via holes 34V connect the pad 34P to the wire 34W and also connect two layers of the wires 34W adjacent to each other in the thickness direction. A plurality of via holes 34V disposed at farthest positions from the second member 40 in the thickness direction extend through a silicon layer and an insulating layer of the surface layer portion of the substrate 33 to the silicon substrate.

Next, advantageous effects of the fifth embodiment will be described. In the first embodiment, part of the second heat transfer path 92 (FIG. 8) includes interlayer insulating films of the multilayer wiring structure 34. By contrast, in the fifth embodiment, part of the second heat transfer path 92 includes the pad 34P, the wires 34W, and the via holes 34V that are disposed in the area coinciding with the second member 40 in plan view. Thus, it is possible to further reduce the thermal resistance in the second heat transfer path 92 as compared to the structure according to the first embodiment. This can further improve the characteristic of releasing heat from the second member 40.

The embodiments described above are mere examples, and as might be expected, the configurations described in the different embodiments may be partially replaced or combined with each other. In particular, almost identical effects and advantages achieved by almost identical configurations in the plurality of embodiments are not mentioned in every embodiment. Moreover, the present disclosure is not limited to the embodiments described above. For example, various modifications, improvements, and combinations would be apparent to those skilled in the art.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A semiconductor module comprising:
a first member having a lower surface and a top surface facing away from each other;
a first conductive raised portion disposed on the lower surface of the first member;
a second member joined to the lower surface of the first member, the second member being smaller than the first member in plan view, and the second member including a semiconductor element inside;
a second conductive raised portion disposed at the second member, the second conductive raised portion being raised in a direction identical to a direction in which the first conductive raised portion is raised;
a module substrate on which the first member and the second member are mounted with the first conductive raised portion interposed between the module substrate and the first member and with the second conductive raised portion interposed between the module substrate and the second member;
a sealing material disposed on a surface of the module substrate, the first member and the second member being mounted on the surface of the module substrate, the sealing material covering at least an area of a surface of the first member, the sealing material having a top surface facing in a direction identical to a direction in which the top surface of the first member faces and also having side surfaces connected to the top surface of the sealing material; and
a metal film disposed on the top surface of the sealing material, the side surfaces of the sealing material, and side surfaces of the module substrate.

2. The semiconductor module according to claim 1, wherein
the top surface of the first member is exposed from the sealing material, and the metal film is in contact with the top surface of the first member.

3. The semiconductor module according to claim 1, wherein
an area of a side surface of the first member is exposed from the sealing material, and the metal film is in contact with the exposed side surface of the first member.

4. The semiconductor module according to claim 1, wherein
the semiconductor element included in the second member constitutes a power amplifier, and
the first member includes a power amplifier control circuit configured to control an operation of the power amplifier,
the semiconductor module further comprising an inter-member connection wire configured to electrically couple the power amplifier and the power amplifier control circuit, the inter-member connection wire being disposed on the lower surface of the first member and a lower surface of the second member.

5. The semiconductor module according to claim 4, wherein
the power amplifier control circuit includes an elemental semiconductor element, and
the semiconductor element included in the second member is configured from a compound semiconductor.

6. The semiconductor module according to claim 1, wherein
the module substrate includes a ground plane disposed at an inner layer of the module substrate, the ground plane being coupled to the metal film at the side surfaces of the module substrate.

7. The semiconductor module according to claim 6, wherein
the module substrate includes a plurality of connection terminals disposed on a surface opposite the surface on which the first member and the second member are mounted, and
at least one of the plurality of connection terminals is coupled to the ground plane.

8. The semiconductor module according to claim 2, wherein
an area of a side surface of the first member is exposed from the sealing material, and the metal film is in contact with the exposed side surface of the first member.

9. The semiconductor module according to claim 2, wherein
the semiconductor element included in the second member constitutes a power amplifier, and
the first member includes a power amplifier control circuit configured to control an operation of the power amplifier,
the semiconductor module further comprising an inter-member connection wire configured to electrically couple the power amplifier and the power amplifier control circuit, the inter-member connection wire being disposed on the lower surface of the first member and a lower surface of the second member.

10. The semiconductor module according to claim 3, wherein
the semiconductor element included in the second member constitutes a power amplifier, and
the first member includes a power amplifier control circuit configured to control an operation of the power amplifier,
the semiconductor module further comprising an inter-member connection wire configured to electrically couple the power amplifier and the power amplifier control circuit, the inter-member connection wire being disposed on the lower surface of the first member and a lower surface of the second member.

11. The semiconductor module according to claim 8, wherein
the semiconductor element included in the second member constitutes a power amplifier, and
the first member includes a power amplifier control circuit configured to control an operation of the power amplifier,
the semiconductor module further comprising an inter-member connection wire configured to electrically couple the power amplifier and the power amplifier control circuit, the inter-member connection wire being disposed on the lower surface of the first member and a lower surface of the second member.

12. The semiconductor module according to claim 9, wherein
the power amplifier control circuit includes an elemental semiconductor element, and
the semiconductor element included in the second member is configured from a compound semiconductor.

13. The semiconductor module according to claim 10, wherein
the power amplifier control circuit includes an elemental semiconductor element, and
the semiconductor element included in the second member is configured from a compound semiconductor.

14. The semiconductor module according to claim 11, wherein
the power amplifier control circuit includes an elemental semiconductor element, and
the semiconductor element included in the second member is configured from a compound semiconductor.

15. The semiconductor module according to claim 2, wherein
the module substrate includes a ground plane disposed at an inner layer of the module substrate, the ground plane being coupled to the metal film at the side surfaces of the module substrate.

16. The semiconductor module according to claim 3, wherein
the module substrate includes a ground plane disposed at an inner layer of the module substrate, the ground plane being coupled to the metal film at the side surfaces of the module substrate.

17. The semiconductor module according to claim 4, wherein
the module substrate includes a ground plane disposed at an inner layer of the module substrate, the ground plane being coupled to the metal film at the side surfaces of the module substrate.

18. The semiconductor module according to claim 5, wherein
the module substrate includes a ground plane disposed at an inner layer of the module substrate, the ground plane being coupled to the metal film at the side surfaces of the module substrate.

19. The semiconductor module according to claim 8, wherein
the module substrate includes a ground plane disposed at an inner layer of the module substrate, the ground plane being coupled to the metal film at the side surfaces of the module substrate.

20. The semiconductor module according to claim 9, wherein
the module substrate includes a ground plane disposed at an inner layer of the module substrate, the ground plane being coupled to the metal film at the side surfaces of the module substrate.
